(19) United States
(12) Patent Application Publication
(10) Pub. No.: US 2018/0130774 A1
(43) Pub. Date: May 10, 2018

(54) PACKAGE STACK STRUCTURE

(71) Applicant: Siliconware Precision Industries Co., Ltd., Taichung (TW)

(72) Inventors: Chang-Fu Lin, Taichung City (TW); Chin-Tsai Yao, Taichung City (TW); Kuo-Hua Yu, Taichung City (TW); Fu-Tang Huang, Taichung City (TW)

(21) Appl. No.: 15/434,824

(22) Filed: Feb. 16, 2017

(30) Foreign Application Priority Data
Nov. 10, 2016 (TW) 105136595

(51) Int. Cl. H01L 25/065; H01L 23/31

(52) U.S. Cl. CPC H01L 25/0657; H01L 23/3121; H01L 2225/06517; H01L 2225/0652; H01L 24/17; H01L 2224/16227; H01L 2225/06572; H01L 2924/15151; H01L 2924/2064; H01L 2224/16113

(57) ABSTRACT

A package stack structure is provided, including a first substrate, a second substrate stacked on the first substrate, and an encapsulant formed between the first substrate and the second substrate. A through hole is formed to penetrate the second substrate and allow the encapsulant to be filled therein, thereby increasing the contact area and hence strengthening the bonding between the encapsulant and the second substrate.

### BACKGROUND

### 1. Technical Field

The present disclosure relates to package structures, and, more particularly, to a package stack structure.

### 2. Description of Related Art

Along with the progress of semiconductor packaging technologies, various package types have been developed for semiconductor devices. To improve electrical performance and save space, a plurality of packages can be stacked to form a package on package (PoP) structure. Such a packaging method allows merging of heterogeneous technologies in a system-in-package (SiP) so as to systematically integrate a plurality of electronic components having different functions, such as a memory, a central processing unit (CPU), a graphics processing unit (GPU), an image application processor, and so on, and therefore is applicable to various thin type electronic products.

FIG. 1 is a schematic cross-sectional view of a conventional package stack structure 1. An interposer 12 is stacked on a packaging substrate 11 through a plurality of solder balls 13. The packaging substrate 11 has a semiconductor element 10 disposed on an upper side thereof and a plurality of solder balls 17 formed on a lower side thereof for being bonded with an electronic device such as a circuit board (not shown). Further, an encapsulant 14 is formed between the packaging substrate 11 and the interposer 12 to encapsulate the semiconductor element 10 and the solder balls 13.

However, a solder mask layer 123 is formed on both upper and lower sides of the interposer 12. After multiple processes, the solder mask layer 123 tends to discolor. As such, delamination may occur between the encapsulant 14 and the interposer 12.

Further, during formation of the encapsulant 14, voids may occur in the encapsulant 14 due to air trapped between the packaging substrate 11 and the interposer 12, thus reducing the product yield.

Therefore, how to overcome the above-described drawbacks has become critical.

### SUMMARY

In view of the above-described drawbacks, the present disclosure provides a package stack structure, which comprises: a first substrate; a second substrate having opposite first and second surfaces and at least one through hole communicating the first and second surfaces, wherein the first surface of the second substrate is stacked on the first substrate through a plurality of conductive elements; and an encapsulant formed between the second substrate and the first substrate and in the through hole.

In an embodiment, the through hole has a width not greater than 50 μm. In another embodiment, the width of the through hole is between 10 μm and 25 μm.

In an embodiment, an insulating layer is formed on the first and second surfaces of the second substrate, and the through hole penetrates the insulating layer. In an embodiment, the insulating layer has an opening communicating with the through hole. The opening can be greater in width than the through hole. In an embodiment, the opening has a width not greater than 100 μm. In another embodiment, at least one of the through hole and the opening forms a “T”, “I” or “□” shape in section.

In an embodiment, the package stack structure further comprises an electronic component disposed on and electrically connected to the first substrate. The through hole can correspond in position to the electronic component. In an embodiment, the through hole is positioned within a projection area of the electronic component on the second substrate. In another embodiment, the through hole is positioned at a corner of the projection area of the electronic component on the second substrate.

In an embodiment, the package stack structure further comprises an electronic component disposed on and electrically connected to the second substrate.

According to the present disclosure, the through hole of the second substrate allows the encapsulant to be formed therein, thereby increasing the contact area and hence strengthening the bonding between the encapsulant and the second substrate. In an embodiment, the opening of the insulating layer communicating with the through hole is greater in width than the through hole, so as to achieve a locking effect when the encapsulant is filled in the through hole and the opening. As such, the present disclosure prevents occurrence of delamination.

Further, the through hole can serve as an air vent during the molding process for forming the encapsulant. The encapsulant flows through the through hole to the second surface of the second substrate, thereby expelling the air out and preventing voids from occurring in the encapsulant.

### BRIEF DESCRIPTION OF DRAWINGS

FIG. 1 is a schematic cross-sectional view of a conventional package stack structure;

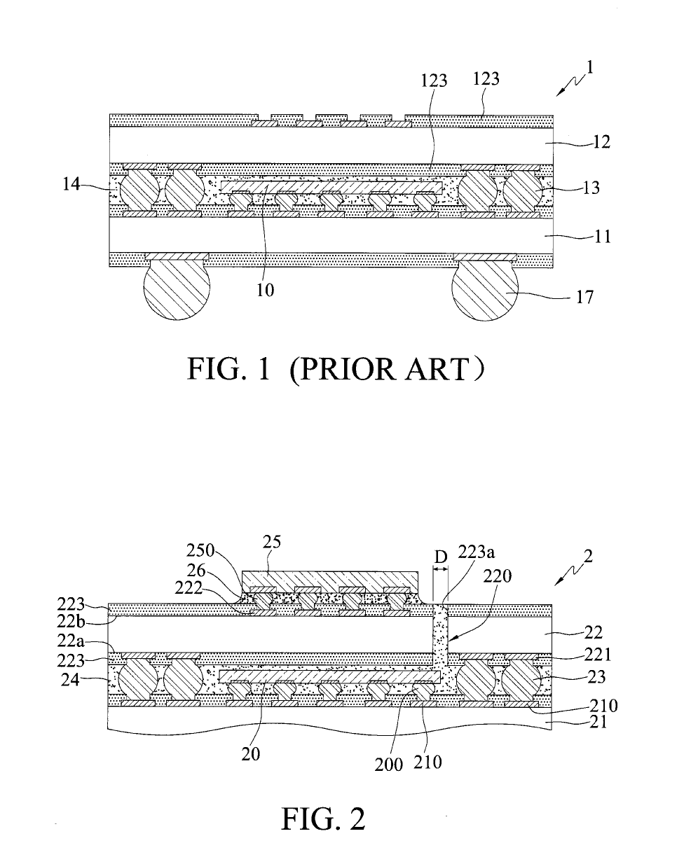

FIG. 2 is a schematic cross-sectional view of a package stack structure according to the present disclosure;

FIGS. 3A to 3D are partially enlarged cross-sectional views showing various embodiments of a through hole of FIG. 2; and

FIGS. 4A to 4C are partial upper views showing various embodiments of the package stack structure of FIG. 2.

### DETAILED DESCRIPTION OF PREFERRED EMBODIMENTS

The following illustrative embodiments are provided to illustrate the disclosure of the present disclosure, these and other advantages and effects can be apparent to those in the art after reading this specification.

It should be noted that all the drawings are not intended to limit the present disclosure. Various modifications and variations can be made without departing from the spirit of the present disclosure. Further, terms such as “first”, “second”, “on”, “a” etc. are merely for illustrative purposes and should not be construed to limit the scope of the present disclosure.

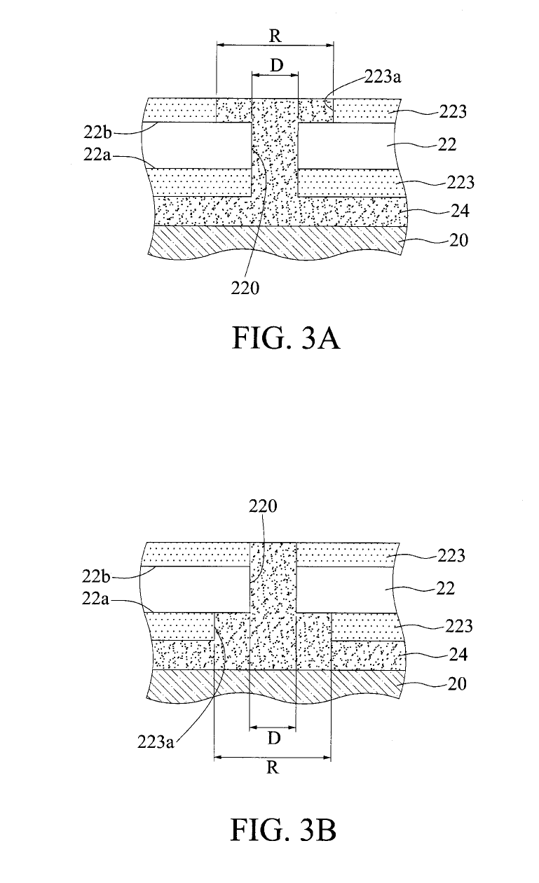

FIG. 2 is a schematic cross-sectional view of a package stack structure 2 according to the present disclosure. The package stack structure 2 has a first substrate 21, a second substrate 22, and a plurality of conductive elements 23 and an encapsulant 24 between the first substrate 21 and the second substrate 22.

The first substrate 21 is a packaging substrate having at least one electronic component 20 disposed thereon.

In an embodiment, the first substrate 21 has a core or coreless structure, which has at least one circuit layer having a plurality of bonding pads 210.

The electronic component 20 is an active component such as a semiconductor chip, a passive component, such as a resistor, a capacitor or an inductor, or a combination thereof. The electronic component 20 is disposed on a portion of the bonding pads 210 through a plurality of solder bumps 200. That is, the electronic component 20 is electrically connected to the first substrate 21 in a flip-chip manner. Alternatively, the electronic component 20 can be electrically connected to the bonding pads 210 through wire bonding.

The second substrate 22 has a first surface 22a, a second surface 22b opposite to the first surface 22a, and at least one through hole 220 communicating the first surface 22a and the second surface 22b.

In an embodiment, the second substrate 22 has a core or coreless structure, which has at least one circuit layer. In an embodiment, the second substrate 22 has a plurality of conductive pads 221 disposed on the first surface 22a and a plurality of conductive pads 222 disposed on the second surface 22b. Further, an insulating layer 223 such as a solder mask layer is formed on the first surface 22a and the second surface 22b of the second substrate 22, and the conductive pads 221, 222 are exposed from the insulating layer 223.

The through hole 220 is formed by laser, mechanical drilling or other means such as sandblasting, filing, cutting, milling, grinding, water jet or etching. The through hole 220 has a width D not greater than 50 μm. Preferably, the width D of the through hole 220 is between 10 and 25 μm.

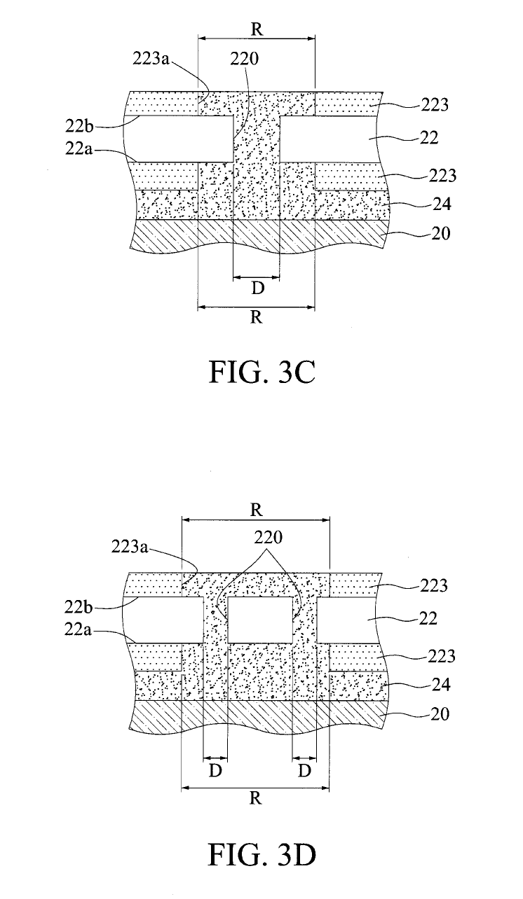

The shape of the through hole 220 can be designed according to practical demands. In an embodiment, the through hole 220 extends to and penetrates the insulating layer 223, and the insulating layer 223 has a corresponding opening 223a. That is, the opening 223a of the insulating layer 223 communicates with the through hole 220. In an embodiment, referring to FIG. 2, the through hole 220 extends into the insulating layer 223 and has a uniform width D. That is, the through hole 220 and the opening 223a have the same width. In another embodiment, referring to FIGS. 3A and 3B, the width R of the opening 223a at one end of the through hole 220 is greater than the width D of the through hole 220, and thus the through hole 220 and the opening 223a form a “T” shape in section. In another embodiment, referring to FIG. 3C, the opening 223a at both ends of the through hole 220 is greater in width than the through hole 220. As such, the opening 223a and the through hole 220 form an “I” shape in section. In further another embodiment, referring to FIG. 3D, at least two through holes 220 are formed, and the through holes 220 and the opening 223a form a “□” shape in section. In an embodiment, the width R of the opening 223a is not greater than 100 μm.

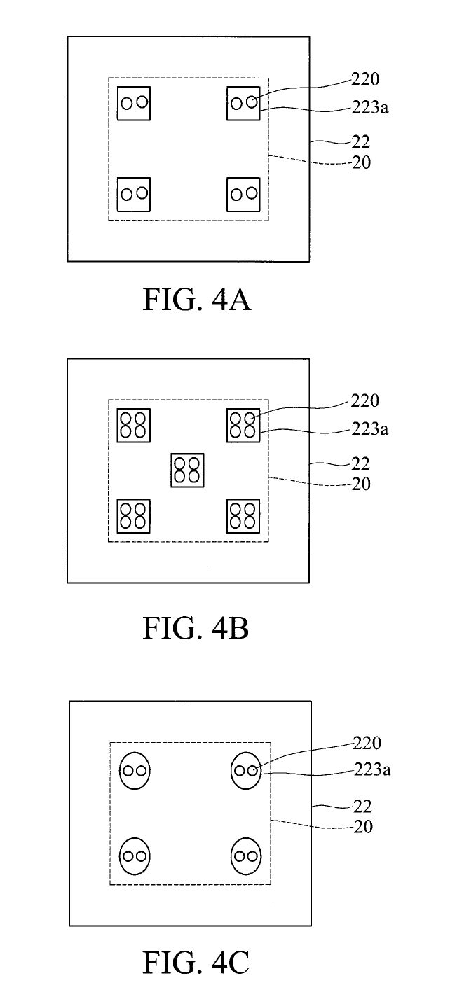

In an embodiment, the through hole 220 of the second substrate 22 corresponds in position to the electronic component 20. Referring to FIGS. 4A to 4C, a plurality of through holes 220 are positioned within a projection area of the electronic component 20 on the second substrate 22. Since delamination likely occurs at four corners of the electronic component 20 due to large stresses, the through holes 220 are preferably positioned at four corners of the projection area of the electronic component 20 on the second substrate 22. Further, referring to FIG. 4B, the through holes 220 can be positioned at the center of the projection area of the electronic component 20 on the second substrate 22. The opening 223a of the insulating layer 223 communicating with the through hole 220 can have a rectangular shape (as shown in FIGS. 4A and 4B) or a circular shape (as shown in FIG. 4C).

The conductive elements 23 bond the first surface 22a of the second substrate 22 to the first substrate 21 so as to stack the second substrate 22 on the first substrate 21. In an embodiment, the conductive elements 23 electrically connect the conductive pads 221 of the second substrate 22 and the bonding pads 210 of the first substrate 21.

In an embodiment, the conductive elements 23 are solder balls or metal posts, for example, electroplated copper posts.

The encapsulant 24 is formed between the first surface 22a of the second substrate 22 and the first substrate 21 and in the through hole 220 to encapsulate the conductive elements 23 and the electronic component 20.

In an embodiment, the encapsulant 24 is made of polyimide, a dry film, an epoxy resin, or a molding compound.

At least one electronic component 25 is disposed on the second surface 22b of the second substrate 22. The electronic component 25 can be a package, an active component such as a semiconductor chip, a passive component such as a resistor, a capacitor or an inductor, or a combination thereof.

In an embodiment, the electronic component 25 is electrically connected to the conductive pads 222 through a plurality of solder bumps 250, and an underfill 26 is formed between the electronic component 25 and the second surface 22b of the second substrate 22 (or the insulating layer 223). It should be understood that the electronic component 25 can be electrically connected to the conductive pads 222 through wire bonding.

According to the present disclosure, the through hole 220 of the package stack structure 2 allows the encapsulant 24 to be formed therein, thus increasing the contact area between the encapsulant 24 and the second substrate 22. Further, the opening 223a of the insulating layer 223 communicating with the through hole 220 is greater in width than the through hole 220 so as to achieve a locking effect when the encapsulant 24 is filled in the through hole 220 and the opening 223a. Therefore, the present disclosure strengthens the bonding between the encapsulant 24 and the second substrate 22 and effectively prevents occurrence of delamination.

Further, the through hole 220 can serve as an air vent during the molding process for forming the encapsulant 24. The encapsulant 24 flows through the through hole 220 to the second surface 22b of the second substrate 22, thus expelling the air out and preventing voids from occurring in the encapsulant 24.

The above-described descriptions of the detailed embodiments are only to illustrate the preferred implementation according to the present disclosure, and it is not to limit the scope of the present disclosure. Accordingly, all modifications and variations completed by those with ordinary skill in the art should fall within the scope of present disclosure defined by the appended claims.

1: A package stack structure, comprising:
a first substrate;
an electronic component disposed on and electrically connected to the first substrate;
a second substrate having opposite first and second surfaces and at least one through hole communicating the first and second surfaces, wherein the first surface of the second substrate is stacked on the first substrate through a plurality of conductive elements, and wherein the through hole is positioned at a corner of a projection area of the electronic component on the second substrate; and
an encapsulant formed between the second substrate and the first substrate and in the through hole.

2: The package stack structure of claim 1, wherein the through hole has a width not greater than 50 μm.

3: The package stack structure of claim 2, wherein the width of the through hole is between 10 μm and 25 μm.

4: The package stack structure of claim 1, further comprising a plurality of insulating layers formed on the first and second surfaces of the second substrate.

5: The package stack structure of claim 4, wherein the through hole penetrates through the insulating layers.

6: The package stack structure of claim 4, wherein at least one of the insulating layers has an opening communicating with the through hole.

7: The package stack structure of claim 6, wherein the opening is greater in width than the through hole.

8: The package stack structure of claim 6, wherein the opening has a width not greater than 100 μm.

9: The package stack structure of claim 6, wherein at least one of the through hole and the opening forms a T, I or Π shape in section.

10. (canceled)

11: The package stack structure of claim 1, wherein the through hole is positioned within a projection area of the electronic component on the second substrate.

12. (canceled)

13: The package stack structure of claim 1, further comprising another electronic component disposed on and electrically connected to the second substrate.
